(19) United States
(12) Patent Application Publication
(10) Pub. No.: US 2026/0323905 A1
(43) Pub. Date: Oct. 15, 2026

(54) DYNAMIC RANDOM ACCESS MEMORY

(71) Applicant: INSTITUTE OF MICROELECTRONICS, CHINESE ACADEMY OF SCIENCES, Beijing (CN)

(72) Inventors: Guanhua YANG, Beijing (CN); Xuanming ZHANG, Beijing (CN); Fuxi LIAO, Beijing (CN); Menghan LIU, Beijing (CN); Kaifei CHEN, Beijing (CN); Zihan LI, Beijing (CN); Naide MAO, Beijing (CN); Nianduan LU, Beijing (CN); Ling LI, Beijing (CN)

(73) Assignee: INSTITUTE OF MICROELECTRONICS, CHINESE ACADEMY OF SCIENCES, Beijing (CN)

(21) Appl. No.: 19/463,434

(22) Filed: Jan. 29, 2026

Related U.S. Application Data
(63) Continuation of application No. PCT/CN2025/088802, filed on Apr. 14, 2025.

(30) Foreign Application Priority Data
Jan. 16, 2025 (CN) 202510072351.1

(51) Int. Cl. H10B 12/00; H10W 20/41; H10W 20/42; H10W 20/43

(52) U.S. Cl. CPC H10B 12/00; H10W 20/422; H10W 20/43; H10W 20/435; H10B 12/01

(57) ABSTRACT

A dynamic random access memory is provided. The dynamic random access memory includes a plurality of memory cells arranged in a three-dimensional array. Each memory cell includes a first transistor and a second transistor. A second source region, a second channel region, and a second drain region are disposed in a first via along a first direction. A second gate is disposed in the first via. A first gate of the second transistor is disposed in a first notch. One of a first source and a first drain that is not electrically connected to the first gate is disposed in a second via. A first source region, a first channel region, and a first drain region are spaced apart along a third direction in a second notch.

### CROSS REFERENCE TO RELATED APPLICATION

This application claims priority to Chinese Patent Application No. 202510072351.1, filed with the China National Intellectual Property Administration (CNIPA) on Jan. 16, 2025 and entitled "DYNAMIC RANDOM ACCESS MEMORY AND MANUFACTURING METHOD THEREOF", which is incorporated herein by reference in its entirety.

### TECHNICAL FIELD

The present disclosure relates to the technical field of memories, and in particular, to a dynamic random access memory (DRAM) and a manufacturing method thereof.

### BACKGROUND

In computer systems, the memory is a critical component for storing data and programs. The dynamic random access memory (DRAM), as an important type of memory, plays a key role in modern computer architectures. The DRAM includes a two-transistor-zero-capacitor (2T0C) memory cell structure. A memory cell of such DRAM consists of two transistors, where one transistor is responsible for selection, and the other transistor is responsible for both selection and charge storage.

In the prior art, memory cells of DRAM are arrayed along the horizontal direction of the wafer, forming two-dimensional (2D) DRAM. However, the development of computer systems has imposed higher requirements on the density of DRAM, and the density of 2D DRAM is limited by process constraints and cannot meet the density requirements.

### SUMMARY

An objective of the present disclosure is to provide a DRAM and a manufacturing method thereof, aiming to achieve simultaneous formation of a multi-layer memory cell array, thereby improving the integration density of the DRAM while ensuring the electrical performance and stability of the memory cells.

To achieve the foregoing objective, according to a first aspect, the present disclosure provides a DRAM, which includes a plurality of memory cells arranged in a three-dimensional array, and a dielectric structure configured to isolate the plurality of memory cells. The plurality of memory cells arranged in the three-dimensional array include a plurality of memory layers spaced apart along a first direction, each of the memory layers includes a plurality of memory groups spaced apart along a second direction, and each of the memory groups includes a plurality of the memory cells spaced apart along a third direction. The first direction, the second direction, and the third direction are different from each other. Each of the memory cells includes a first transistor and a second transistor distributed along the third direction. The second transistor has a double-gate structure. In the same memory cell, one of a first source and a first drain of the first transistor is electrically connected to a first gate of the second transistor. First vias and second vias distributed at intervals along the third direction are provided in the dielectric structure. A second source region, a second channel region, and a second drain region of the second transistor are disposed in the first via along the first direction. A second gate of the second transistor is disposed in the first via, and the second channel region of the second transistor surrounds a periphery of the second gate. A portion of the dielectric structure corresponding to the second channel region of the second transistor is provided with a first notch recessed inward, and the first gate of the second transistor is disposed in the first notch. One of the first source and the first drain that is not electrically connected to the first gate is disposed in the second via. A portion of the dielectric structure corresponding to a portion of the second via is provided with a second notch recessed inward, and the second notch is communicated with the first notch. A first source region, a first channel region, and a first drain region of the first transistor are distributed in the second notch along the third direction.

With the aforementioned technical solution, the DRAM provided in the present disclosure not only includes multiple memory groups spaced apart along the second direction within the same layer, but also multiple memory layers spaced apart along the first direction. In this case, the memory cells are arranged in a three-dimensional array. Compared to a two-dimensional dynamic random access memory (2D DRAM) having only a single memory layer, each memory layer in the present disclosure can form a structure analogous to the conventional 2D DRAM, while the multiple memory layers stacked along the first direction in the present disclosure can increase the storage density of the provided DRAM multiplicatively, effectively solving the problem of low density in the 2D DRAM. Furthermore, the first via is communicated with the first notch, and the second via is connected to the second notch. Since the aforementioned structures of the first transistor and the aforementioned structures of the second transistor in the memory cell are all disposed in the first via, the second via, the first notch, and the second notch, during manufacture of the DRAM provided in the present disclosure, a multi-layer memory cell array can be formed in one process through operations on the first via and the second via. This significantly improves the integration density and storage density of the DRAM while ensuring the electrical performance and stability of the memory cells.

Additionally, the first transistor serves as a write transistor, and the second transistor serves as a read transistor. Based on this, during the manufacture of the DRAM provided in the present disclosure, process variations may cause deviations in the structures of the memory cells, particularly the second transistor, from the design, resulting in different threshold voltages for the second transistors in different memory cells. During data reading, this may lead to data errors. Based on this, the second transistor has a double-gate structure, allowing the threshold voltage of the second transistor to be adjusted and compensated via the second gate of the second transistor, thereby preventing data reading errors and improving the data accuracy of the DRAM provided in the present disclosure.

In one possible implementation, the first transistor has a double-gate structure; a third gate and a fourth gate of the first transistor are disposed at two sides of the first channel region along the third direction, respectively.

Conventional transistors have only one gate to control the current in the channel region, whereas with the aforementioned technical solution, the first transistor provided in the present disclosure has two gates. The double-gate transistor can have twice the gate control area for the same channel region area, effectively enhancing the control capability of the gates over the channel region. This enables finer and more flexible control over carriers in the channel region by the gates, allowing more effective regulation of current turn-on and turn-off, thereby improving the switching performance of the transistor provided in the present disclosure. It can effectively suppress short-channel effects, which is beneficial for further reducing the size of the transistor provided in the present disclosure, thus increasing the storage density of the DRAM provided in the present disclosure. For example, under low-voltage operation, the double-gate structure of the first transistor can control the current more precisely, achieving faster switching speed, which helps to reduce the power consumption of the DRAM provided in the present disclosure.

In one possible implementation, a gate structure of the first transistor is disposed in the second notch and is located on at least one side of the first channel region along the first direction; the one of the first source and the first drain that is not electrically connected to the first gate is isolated from the gate structure by a first gate dielectric layer of the first transistor.

With the aforementioned technical solution, the one of the first source and the first drain that is not electrically connected to the first gate is in close contact with the gate structure, which helps to reduce the area occupied by the one of the first source and the first drain that is not electrically connected to the first gate, thereby reducing the area occupied by the first transistor. This facilitates the one-time formation of a multi-layer memory cell array, significantly improving the integration density of the DRAM while ensuring the electrical performance and stability of the memory cells.

In one possible implementation, a second source and a second drain of the second transistor are disposed in a third notch and a fourth notch, respectively. The third notch and the fourth notch are disposed at two sides of the first gate along the first direction, respectively. The second source is electrically connected to the second source region; and the second drain is electrically connected to the second drain region.

With the aforementioned technical solution, the third notch and the fourth notch are formed at two sides of the first notch along the third direction and are connected to the first via. The second transistor has a vertical channel structure, which reduces the area occupied by the second source region, the second channel region, and the second drain region of the second transistor while ensuring the channel length of the second transistor, thereby reducing the area occupied by the second transistor and improving the storage density of the DRAM. Moreover, the second source, the second drain, and the first gate in the second transistor are vertically stacked along the first direction, reducing the area occupied by the second transistor and improving the storage density of the DRAM. Meanwhile, the vertical stacking of the second source region, the second channel region, and the second drain region in the first via allows the second source region, the second channel region, and the second drain region of the same second transistor to be formed in the first via through a single deposition step, and also allows the second source regions, the second channel regions, and the second drain regions of different second transistors connected via the first via to be formed in the first via through a single deposition step. This facilitates the one-time formation of a multi-layer memory cell array, significantly improving the integration density of the DRAM while ensuring the electrical performance and stability of the memory cells.

In one possible implementation, the first transistor is an indium zinc oxide thin-film transistor, a tin-doped indium oxide thin-film transistor, an indium oxide thin-film transistor, a zinc oxide thin-film transistor, or a titanium oxide thin-film transistor.

With the above technical solution, the aforementioned metal oxide thin-film transistors have low off-state current, thereby achieving low off-state power consumption for the first transistor, which helps to reduce the power consumption of the DRAM provided in the present disclosure. Moreover, the first transistor serves as a write transistor. Based on this, since the aforementioned metal oxide thin-film transistors have low off-state current, they can significantly slow down the discharge rate of the gate capacitance of the second transistor through the channel of the first transistor, thereby substantially extending the retention time of the gate capacitance of the second transistor. This reduces the refresh frequency of the DRAM provided in the present disclosure, thus lowering the power consumption of the DRAM provided in the present disclosure. The first transistor is one of the aforementioned metal oxide thin-film transistors. Therefore, the first transistor has a relatively high carrier mobility, enabling faster signal transmission and switching speed for the first transistor, thereby improving the operating efficiency and response speed of the DRAM provided in the present disclosure. Meanwhile, during the manufacture of the DRAM provided in the present disclosure, the aforementioned metal oxide thin-film transistors can be fabricated using low-temperature processes. Low-temperature processes can reduce the need for expensive high-temperature equipment and complex process steps, thereby lowering costs. In addition, the channel regions of the aforementioned metal oxide thin-film transistors can be formed in parallel through processes such as deposition, allowing the first channel regions in multiple first transistors to be formed simultaneously. This facilitates the simultaneous formation of the first transistors in multiple memory cells, thereby enabling the one-time formation of a multi-layer memory cell array. This significantly improves the integration density of the DRAM while ensuring the electrical performance and stability of the memory cells.

In one possible implementation, the one of the first source and the first drain that is electrically connected to the first gate is integrally continuous with the first gate.

With the above solution, during the manufacture of the DRAM provided in the present disclosure, the one of the first source and the first drain that is electrically connected to the first gate can be formed in the same process step with the first gate, reducing the number of process steps. This facilitates the one-time formation of a multi-layer memory cell array, significantly improving the integration density of the DRAM while ensuring the electrical performance and stability of the memory cells. Moreover, since the aforementioned two structures are integrally continuous, no additional structures are required to connect them, which helps to reduce the area occupied by the memory cell, thereby increasing the density of the DRAM provided in the present disclosure.

According to a second aspect, the present disclosure further provides a manufacturing method of a DRAM. The manufacturing method of a DRAM includes forming a plurality of memory cells arranged in a three-dimensional array, and forming a dielectric structure configured to isolate the plurality of memory cells. The plurality of memory cells arranged in the three-dimensional array include a plurality of memory layers spaced apart along a first direction, each of the memory layers includes a plurality of memory groups spaced apart along a second direction, and each of the memory groups includes a plurality of the memory cells spaced apart along a third direction. The first direction, the second direction, and the third direction are different from each other. Each of the memory cells includes a first transistor and a second transistor distributed along the third direction. The second transistor has a double-gate structure. In the same memory cell, one of a first source and a first drain of the first transistor is electrically connected to a first gate of the second transistor. First vias and second vias distributed at intervals along the third direction are provided in the dielectric structure. A second source region, a second channel region, and a second drain region of the second transistor are disposed in the first via along the first direction. A second gate of the second transistor is disposed in the first via, and the second channel region of the second transistor surrounds a periphery of the second gate. A portion of the dielectric structure corresponding to the second channel region of the second transistor is provided with a first notch recessed inward, and the first gate of the second transistor is disposed in the first notch. One of the first source and the first drain that is not electrically connected to the first gate is disposed in the second via. A portion of the dielectric structure corresponding to a portion of the second via is provided with a second notch recessed inward, and the second notch is communicated with the first notch. A first source region, a first channel region, and a first drain region of the first transistor are distributed in the second notch along the third direction.

Compared with the prior art, the beneficial effects of the manufacturing method of a DRAM provided in the present disclosure are the same as those of the DRAM according to the first aspect, and thus will not be repeated here.

In one possible implementation, the forming the plurality of memory cells arranged in the three-dimensional array and forming the dielectric structure configured to isolate the plurality of memory cells from each other are implemented as follows: A stack structure, and a first dielectric filling portion and a second dielectric filling portion that penetrate through the stack structure along the first direction are formed, where the stack structure includes a plurality of stack units stacked along the first direction. The stack units each include two first dielectric layers spaced apart along the first direction, and a laminate located between the two first dielectric layers. The laminate includes two metal layers spaced apart along the first direction, and a second dielectric layer located between the two metal layers. Materials of the first dielectric layer, the metal layer, and the second dielectric layer are different from each other. Third vias and fourth vias penetrating along the first direction are provided in the stack structure; the third vias and the fourth vias are spaced apart. The third via is filled with a first dielectric filling portion, and the fourth via is filled with the second dielectric filling portion. Next, a plurality of the first vias that penetrate through the stack structure and that are spaced apart along the second direction are formed. Then, edge portions of the two metal layers adjacent to the first via are selectively etched along the third direction, to form a third notch and a fourth notch. A dielectric isolation layer is then formed in the third notch, the fourth notch, and the first via. Next, the second source of the second transistor is formed in the third notch, and the second drain of the second transistor is formed in the fourth notch. Then, the second source region, the second channel region, and the second drain region of the second transistor are formed in the first via along the first direction, where the second source is connected to the second source region; the second drain is connected to the second drain region. After that, a second gate dielectric layer of the second transistor is formed in the first via. The second gate dielectric layer is formed on the second source region, the second channel region, and the second drain region. Next, the second gate of the second transistor is formed in the first via. Further, a plurality of the second vias that penetrate through the stack structure and that are spaced apart along the second direction are formed. Then, the second dielectric layer is partially removed to form the first notch and the second notch, and remaining portions of the two metal layers form a gate structure of the first transistor. Next, a first gate dielectric layer of the first transistor is formed in the second notch and the second via. Then, the first gate of the second transistor and the one of the first source and first drain that is electrically connected to the first gate are formed in the first notch. Moreover, the first source region, the first channel region, and the first drain region of the first transistor are formed in the second notch. Finally, the one of the first source and the first drain that is not electrically connected to the first gate is formed in the second via.

With the above technical solution, the first via is communicated with the first notch, the first via is connected to the third notch, the first via is connected to the fourth notch, and the second via is connected to the second notch. After the first via and the second via are formed, the aforementioned structures of the first transistor and the second transistor are formed through processing in the first via and the second via, thereby enabling simultaneous fabrication of memory cells disposed in the same first via. The stack structure includes multiple first vias, allowing simultaneous processing of multiple memory cells located in the multiple first vias, thereby enabling simultaneous manufacturing of all memory cells in the DRAM. This facilitates the one-time formation of a multi-layer memory cell array, significantly improving the integration density of the DRAM while ensuring the electrical performance and stability of the memory cells.

In one possible implementation, the forming the stack structure, and the first dielectric filling portion and the second dielectric filling portion that penetrate through the stack structure along the first direction is implemented as follows: a stack material layer is formed. The stack material layer includes the plurality of stack units stacked along the first direction. Next, the third vias and the fourth vias penetrating through the stack material layer are formed. Along the second direction, the third via is provided between two adjacent ones of the first vias; and along the second direction, the fourth via is provided between two adjacent ones of the second vias. Next, the third via is filled with the first dielectric filling portion, and the fourth via is filled with the second dielectric filling portion.

With the above technical solution, the third via is spaced apart from the first via, and the fourth via is spaced apart from the second via. The first dielectric filling portion filled in the third via and the second dielectric filling portion filled in the fourth via serve as isolation layers between memory cells adjacent to each other in the second direction, helping to prevent leakage between memory cells adjacent to each other in the second direction. Moreover, in the step of partially removing the second dielectric layer, the two metal layers in the stack unit become suspended. The first dielectric filling portion and the second dielectric filling portion can provide support, preventing bending of the stack structure, which improves the structural regularity of the memory cells. This ensures the normal operation and performance stability of the memory cells manufactured by the manufacturing method of a DRAM provided in the present disclosure, thereby improving yield.

In one possible implementation, the partially removing the second dielectric layer further includes: partially removing the second dielectric layer that is located between the first via and the second via in the third direction and that is adjacent to the second via, such that a remaining portion of the second dielectric layer forms a second dielectric portion. Along the second direction, the second dielectric portion electrically isolates the first source regions, the first channel regions, the first drain regions, and the first gates of two adjacent ones of the memory cells.

With the above technical solution, the second dielectric portion isolates the first source regions, the first channel regions, the first drain regions, and the first gates in two memory cells adjacent to each other in the second direction, thereby achieving isolation of data stored in the two adjacent memory cells. Additionally, the second dielectric portion can also serve as a support, preventing the stack structure from bending after formation of the first notch and the second notch, which benefits the structural regularity of the memory cells. This ensures the normal operation and performance stability of the memory cells manufactured by the manufacturing method of a DRAM provided in the present disclosure, thereby improving yield.

### BRIEF DESCRIPTION OF THE DRAWINGS

The accompanying drawings described herein are provided for further understanding of this application, and constitute a part of this application. The exemplary embodiments of this application and illustrations thereof are intended to explain this application, but do not constitute inappropriate limitations to this application. In the accompanying drawings:

FIG. 1(a) is a front view of a structure of a DRAM according to an embodiment of the present disclosure;

FIG. 1(b) is a top view of a structure of a DRAM according to an embodiment of the present disclosure;

FIG. 2 is a flowchart of a manufacturing method of a DRAM according to an embodiment of the present disclosure;

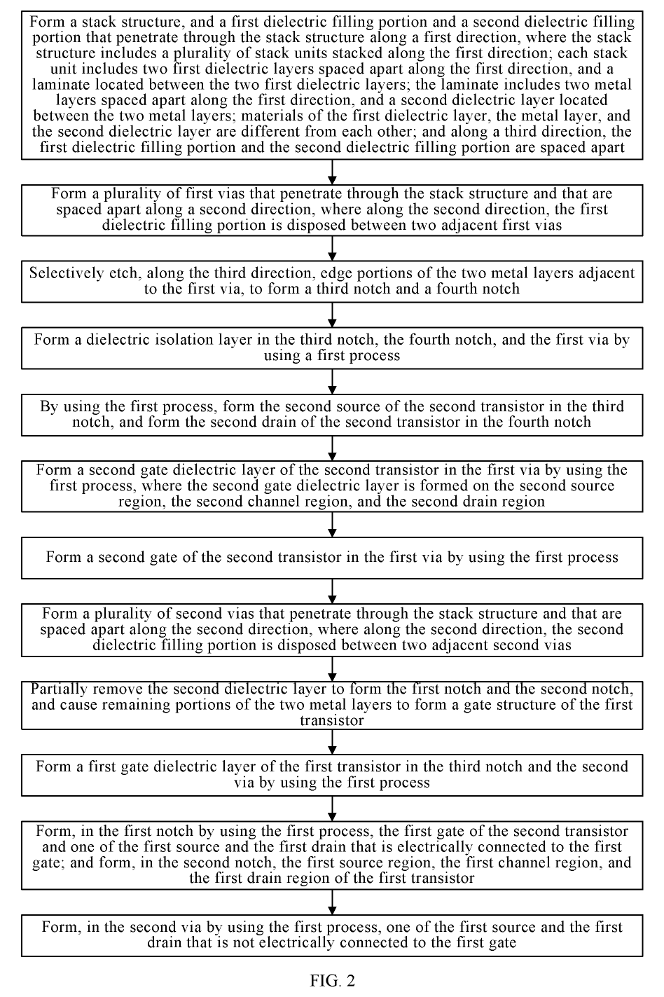

FIG. 3(a) is a front view in a schematic diagram illustrating the formation of a stack structure according to an embodiment of the present disclosure;

FIG. 3(b) is a top view in a schematic diagram illustrating the formation of a stack structure according to an embodiment of the present disclosure;

FIG. 4 is a flowchart of forming a stack structure according to an embodiment of the present disclosure;

FIG. 5 is a front view in a schematic diagram illustrating the formation of a third via and a fourth via according to an embodiment of the present disclosure;

FIG. 6(a) is a front view in a schematic diagram illustrating filling a third via with a first dielectric filling portion and filling a fourth via with a second dielectric filling portion according to an embodiment of the present disclosure;

FIG. 6(b) is a top view in a schematic diagram illustrating filling a third via with a first dielectric filling portion and filling a fourth via with a second dielectric filling portion according to an embodiment of the present disclosure;

FIG. 7(a) is a front view in a schematic diagram illustrating the formation of a first via, a third notch, and a fourth notch according to an embodiment of the present disclosure;

FIG. 7(b) is a top view in a schematic diagram illustrating the formation of a first via, a third notch, and a fourth notch according to an embodiment of the present disclosure;

FIG. 8(a) is a front view in a schematic diagram illustrating the formation of a dielectric isolation layer according to an embodiment of the present disclosure;

FIG. 8(b) is a top view in a schematic diagram illustrating the formation of a dielectric isolation layer according to an embodiment of the present disclosure;

FIG. 9(a) is a front view in a schematic diagram illustrating the formation of a first source and a first drain according to an embodiment of the present disclosure;

FIG. 9(b) is a top view in a schematic diagram illustrating the formation of a first source and a first drain according to an embodiment of the present disclosure;

FIG. 10(a) is a front view in a schematic diagram illustrating the formation of a second source region, a second channel region, a second drain region, a second gate dielectric layer, and a second gate according to an embodiment of the present disclosure;

FIG. 10(b) is a top view in a schematic diagram illustrating the formation of a second source region, a second channel region, a second drain region, a second gate dielectric layer, and a second gate according to an embodiment of the present disclosure;

FIG. 11(a) is a front view in a schematic diagram illustrating the formation of a second via according to an embodiment of the present disclosure;

FIG. 11(b) is a top view in a schematic diagram illustrating the formation of a second via according to an embodiment of the present disclosure;

FIG. 12(a) is a front view in a schematic diagram illustrating partial removal of a second dielectric layer according to an embodiment of the present disclosure;

FIG. 12(b) is a top view in a schematic diagram illustrating partial removal of a second dielectric layer according to an embodiment of the present disclosure;

FIG. 12(c) is a cross-sectional view taken along line A-A' in FIG. 12(a), illustrating partial removal of a second dielectric layer according to an embodiment of the present disclosure;

FIG. 13(a) is a front view in a schematic diagram illustrating the formation of a first gate dielectric layer according to an embodiment of the present disclosure;

FIG. 13(b) is a top view in a schematic diagram illustrating the formation of a first gate dielectric layer according to an embodiment of the present disclosure;

FIG. 14(a) is a front view in a schematic diagram illustrating the formation of a first source region, a first channel region, a first drain region, a first gate, and the one of a first source and a first drain electrically connected to the first gate according to an embodiment of the present disclosure;

FIG. 14(b) is a top view in a schematic diagram illustrating the formation of a first source region, a first channel region, a first drain region, a first gate, and the one of a first source and a first drain electrically connected to the first gate according to an embodiment of the present disclosure;

FIG. 15(a) is a front view in a schematic diagram illustrating the formation of the one of a first source and a first drain that is not electrically connected to the first gate according to an embodiment of the present disclosure; and

FIG. 15(b) is a top view in a schematic diagram illustrating the formation of the one of a first source and a first drain that is not electrically connected to the first gate according to an embodiment of the present disclosure.

### REFERENCE NUMERALS

110 - First dielectric portion; 111 - First dielectric layer; 120 - Second dielectric portion; 121 - Second dielectric layer; 122 - First notch; 123 - Second notch; 130 - First dielectric filling portion; 131 - Third via; 140 - Second dielectric filling portion; 141 - Fourth via; 150 - Third dielectric filling portion;

200 - First transistor; 211 - First source region; 212 - First channel region; 213 - First drain region; 220 - Gate structure; 221 - Third gate; 222 - Fourth gate; 223 - Metal layer; 231 - First source; 232 - First drain; 240 - First gate dielectric layer; 250 - Second via;

300 - Second transistor; 311 - Second source region; 312 - Second channel region; 313 - Second drain region; 321 - First gate; 322 - Second gate; 331 - Second source; 332 - Second drain; 333 - Third notch; 334 - Fourth notch; 341 - Dielectric isolation layer; 342 - Second gate dielectric layer; 340 - First via;

400 - Memory cell.

### DETAILED DESCRIPTION OF THE EMBODIMENTS

To make the to-be-resolved technical problems, technical solutions and beneficial effects of the embodiments of the present disclosure clearer, the embodiments of the present disclosure are described in further detail below with reference to the drawings and embodiments. It should be understood that the specific embodiments described herein are merely intended to explain the embodiments of the present disclosure, rather than to limit the embodiments of the present disclosure.

It should be noted that when a component is "fixed" or "provided" on another component, the component may be "fixed" or "provided" on the another component directly or indirectly. When a component is "connected" to another component, the component may be "connected" to the another component directly or indirectly.

In addition, the terms "first" and "second" are merely intended for a purpose of description, and shall not be understood as an indication or implication of relative importance or implicit indication of a quantity of indicated technical features. Thus, features defined with "first" and "second" may explicitly or implicitly include one or more of the features. In the description of the embodiments of the present disclosure, "a plurality of" means two or more, unless otherwise specifically defined. In the description of the present application, "multiple" means two or more, unless otherwise specifically defined.

In the description of the embodiments of the present disclosure, it needs to be understood the orientation or positional relationships indicated by terms, such as ''up'', ''down'', ''front'', ''rear'', ''left'', and ''right'', are based on the orientation or positional relationship shown in the accompanying drawings, are merely for facilitating the description of the embodiments of the present disclosure and simplifying the description, rather than indicating or implying that an apparatus or element referred to must have a particular orientation or be constructed and operated in a particular orientation, and therefore shall not be interpreted as limiting the embodiments of the present disclosure.

In the description of the embodiments of the present disclosure, it should be noted that unless otherwise expressly specified, terms such as "mounted", "connected to", and "connected with" should be comprehended in a broad sense. For example, the "connection" may be a fixed connection, a removable connection, or an integral connection; may be a mechanical connection or an electrical connection; may be a direct connection or an indirect connection via an intermediate medium; or may be an interconnection or an interaction relationship between two elements. Those of ordinary skill in the art may understand specific meanings of the foregoing terms in the embodiments of the present disclosure based on a specific situation.

In computer systems, memory is a critical component for storing data and programs. Dynamic random access memory (DRAM), as an important type of memory, plays a key role in modern computer architectures. A typical DRAM includes a 2T0C memory cell structure. A memory cell of such DRAM consists of two transistors, where one transistor is responsible for selection, and the other transistor is responsible for both selection and charge storage.

In the prior art, memory cells of DRAM are arrayed along the horizontal direction of the wafer, forming 2D DRAM. However, the development of computer systems has imposed higher requirements on the density of DRAM, and the density of 2D DRAM is limited by process constraints and cannot meet the density requirements.

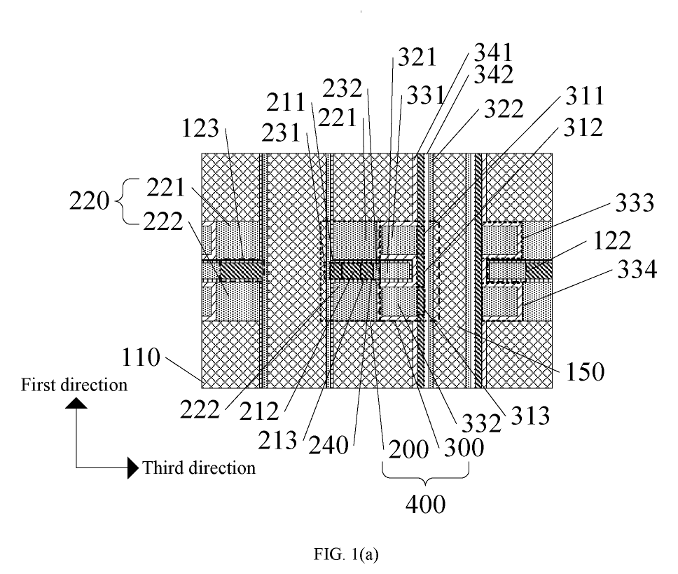

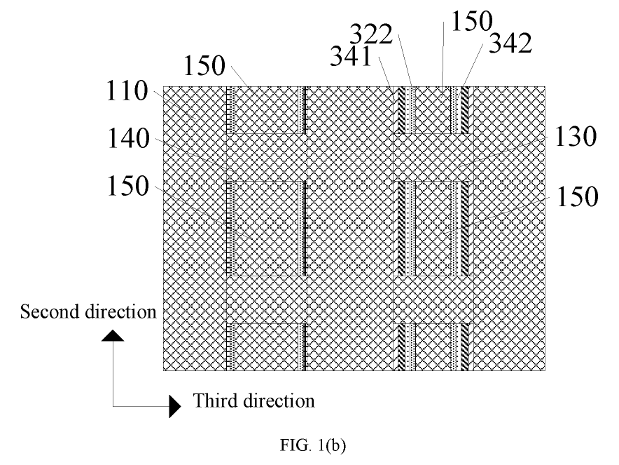

To resolve the foregoing problem, according to a first aspect, an embodiment of the present disclosure provides a DRAM. Referring to FIGS. 1(a) and 1(b) , the DRAM includes a plurality of memory cells 400 arranged in a three-dimensional array and a dielectric structure configured to isolate different memory cells 400. The plurality of memory cells 400 arranged in the three-dimensional array include a plurality of memory layers spaced apart along a first direction, each of the memory layers includes a plurality of memory groups spaced apart along a second direction, and each of the memory groups includes a plurality of the memory cells 400 spaced apart along a third direction. The first direction, the second direction, and the third direction are different from each other. Each of the memory cells 400 includes a first transistor 200 and a second transistor 300 distributed along the third direction. The second transistor 300 has a double-gate structure. In the same memory cell 400, one of a first source 231 and a first drain 232 of the first transistor 200 is electrically connected to a first gate 321 of the second transistor 300. A first via 340 and a second via 250 spaced apart along the third direction are provided in the dielectric structure. A second source region 311, a second channel region 312, and a second drain region 313 of the second transistor 300 are disposed in the first via along the first direction 340. A second gate 322 of the second transistor 300 is disposed in the first via 340, and the second channel region 312 of the second transistor 300 surrounds a periphery of the second gate 322. A portion of the dielectric structure corresponding to the second channel region 312 of the second transistor 300 is provided with a first notch 122 recessed inward, and the first gate 321 of the second transistor 300 is disposed in the first notch 122. One of the first source 231 and the first drain 232 that is not electrically connected to the first gate 321 is disposed in the second via 250. A portion of the dielectric structure corresponding to a portion of the second via 250 is provided with a second notch 123 recessed inward, and the second notch 123 is communicated with the first notch 122. A first source region 211, a first channel region 212, and a first drain region 213 of the first transistor 200 are distributed in the second notch along the third direction 123.

With the aforementioned technical solution, referring to FIGS. 1(a) and 1(b), the DRAM provided in the embodiment of the present disclosure not only includes multiple memory groups spaced apart along the second direction within the same layer, but also multiple memory layers spaced apart along the first direction. In this case, the memory cells 400 are arranged in a three-dimensional array. Compared to a 2D DRAM having only a single memory layer, each memory layer in the embodiment of the present disclosure can form a structure analogous to the conventional 2D DRAM, while the multiple memory layers stacked along the first direction in the embodiment of the present disclosure can increase the storage density of the DRAM provided in the embodiment of the present disclosure multiplicatively, effectively solving the problem of low density in the 2D DRAM. Furthermore, the first via 340 is communicated with the first notch 122, and the second via 250 is connected to the second notch 123. Since the aforementioned structures of the first transistor 200 and the aforementioned structures of the second transistor 300 in the memory cell 400 are all disposed in the first via 340, the second via 250, the first notch 122, and the second notch 123, during manufacture of the DRAM provided in the embodiment of the present disclosure, a multi-layer memory cell array can be formed in one process through operations on the first via 340 and the second via 250. This significantly improves the integration density and storage density of the DRAM while ensuring the electrical performance and stability of the memory cells 400.

Additionally, the first transistor serves as a write transistor, and the second transistor serves as a read transistor. Based on this, during the manufacture of the DRAM provided in the embodiment of the present disclosure, process variations may cause deviations in the structures of the memory cells, particularly the second transistor, from the design, resulting in different threshold voltages for the second transistors in different memory cells. During data reading, this may lead to data errors. Based on this, the second transistor has a double-gate structure, allowing the threshold voltage of the second transistor to be adjusted and compensated via the second gate of the second transistor, thereby preventing data reading errors and improving the data accuracy of the DRAM provided in the embodiment of the present disclosure.

In practical applications, the specific arrangement directions and distribution of different memory cells are not specifically limited in the embodiment of the present disclosure, as long as the different memory cells are arranged in a three-dimensional array. As for the specific directions represented by the aforementioned first direction, second direction, and third direction, there are no specific limitations, as long as any two of the three directions are different.

For example, the first direction is the height direction of the DRAM provided by the embodiment of the present disclosure. Furthermore, the second direction and the third direction can be determined based on the distribution of different memory cells 400 within the same memory layer. For example, referring to FIGS. 1(a) and 1(b) , when different memory cells 400 in the same memory layer are distributed in a rectangular array, the second direction and the third direction can be the directions of the length and width of the rectangular array, respectively. In another example, when different memory cells 400 in the same memory layer are distributed in a parallelogram array, the second direction and the third direction can be the directions of two adjacent sides of the parallelogram array, respectively. In further another example, when different memory cells 400 in the same memory layer are distributed in a concentric circular array, the second direction and the third direction can be the radial direction and the circumferential direction of the concentric circular array, respectively. It can be understood that when the distribution of memory cells in the same memory layer varies, the second direction and the third direction can be changed accordingly.

The structure and materials of the first transistor are further explained below.

The device type of the first transistor is not specifically limited in the embodiments of the present disclosure and can be determined based on actual requirements.

For example, the first transistor is an indium zinc oxide thin-film transistor, a tin-doped indium oxide thin-film transistor, an indium oxide thin-film transistor, a zinc oxide thin-film transistor, or a titanium oxide thin-film transistor.

With the above technical solution, the aforementioned metal oxide thin-film transistors have low off-state current, thereby achieving low off-state power consumption for the first transistor, which helps to reduce the power consumption of the DRAM provided in the embodiment of the present disclosure. Moreover, the first transistor serves as a write transistor, and the second transistor serves as a read transistor. Based on this, since the aforementioned metal oxide thin-film transistors have low off-state current, they can significantly slow down the discharge rate of the gate capacitance of the second transistor through the channel of the first transistor, thereby substantially extending the retention time of the gate capacitance of the second transistor. This reduces the refresh frequency of the DRAM provided in the embodiment of the present disclosure, thus lowering the power consumption of the DRAM provided in the embodiment of the present disclosure. The first transistor is one of the aforementioned metal oxide thin-film transistors. Therefore, the first transistor has a relatively high carrier mobility, enabling faster signal transmission and switching speed for the first transistor, thereby improving the operating efficiency and response speed of the DRAM provided in the embodiment of the present disclosure. Meanwhile, during the manufacture of the DRAM provided in the embodiment of the present disclosure, the channel regions of the aforementioned metal oxide thin-film transistors can be fabricated using low-temperature processes. Low-temperature processes can reduce the need for expensive high-temperature equipment and complex process steps, thereby lowering costs. In addition, the channel regions of the aforementioned metal oxide thin-film transistors can be formed in parallel through processes such as deposition, allowing the first channel regions in multiple first transistors to be formed simultaneously. This facilitates the simultaneous formation of the first transistors in multiple memory cells, thereby enabling the one-time formation of a multi-layer memory cell array. This significantly improves the integration density of the DRAM while ensuring the electrical performance and stability of the memory cells. Moreover, in the DRAM provided in the embodiment of the present disclosure, selecting the aforementioned types of transistors as the first transistor provides a wider range of optional device types for the first transistor, thereby meeting the parameter requirements of the memory cells for the read transistor, such as switching speed, power consumption, conductivity type, and operating voltage.

It is understandable that when the device type of the first transistor is any of the above, the materials of the first source region, the first channel region, and the first drain region are also determined. For example, when the first transistor is a tin-doped indium oxide thin-film transistor, the materials of the first source region, the first channel region, and the first drain region are all tin-doped indium oxide.

By way of example, referring to FIGS. 1(a) and (1b) , the first transistor 200 includes: a first source 231, a first drain 232, a gate structure 220, a first source region 211, a first channel region 212, a first drain region 213, and a first gate dielectric layer 240. The first source region 211, the first channel region 212, and the first drain region 213 are distributed in the second notch 123 along the third direction. The first drain 232 is electrically connected to the first drain region 213 and is also disposed in the second notch 123. The second notch 123 is recessed inward from the second via 250. The first source 231 is electrically connected to the first source region 211 and is disposed in the second via 250. In other words, the first source 231 is disposed at the top of the second notch 123, and along the third direction, the first source 231, the first source region 211, the first channel region 212, the first drain region 213, and the first drain 232 are distributed sequentially. The gate structure 220 is disposed in the second notch 123 and located on at least one side of the first channel region 212 along the first direction. A first gate dielectric layer 240 is further disposed between the gate structure 220 and the first channel region 212 of the first transistor 200. The one of the first source 231 and the first drain 232 that is not electrically connected to the first gate, namely, the first source 231 in the figure, is isolated from the gate structure 220 by the first gate dielectric layer 240 of the first transistor 200.

With the aforementioned technical solution, referring to FIGS. 1(a) and (1b) , the one of the first source 231 and the first drain 232 that is not electrically connected to the first gate 321 is in close contact with the gate structure 220, which helps to reduce the area occupied by the one of the first source 231 and the first drain 232 that is not electrically connected to the first gate 321, thereby reducing the area occupied by the first transistor 200. This facilitates the one-time formation of a multi-layer memory cell array, significantly improving the integration density of the DRAM while ensuring the electrical performance and stability of the memory cells. Moreover, the second notch 123 is connected to the second via 250. The first source region 211, the first channel region 212, and the first drain region 213 of the same first transistor 200 can be formed in the second via 250 through a single deposition step; the first source regions 211, the first channel regions 212, and the first drain regions 213 of different first transistors 200 connected via the first via can also be formed in the second via 250 through a single deposition step. This facilitates the one-time formation of a multi-layer memory cell array, significantly improving the integration density of the DRAM while ensuring the electrical performance and stability of the memory cells.

Regarding the gate structure 220, referring to FIGS. 1(a) and(1b) , the gate structure 220 is disposed in the second notch 123 and located on at least one side of the first channel region 212 along the first direction. During manufacture of the gate structure 220 disposed in the second notch 123, operations on multiple second vias enable the one-time manufacture of the gate structures 220 in all the memory cells 400. This facilitates the one-time formation of a multi-layer memory cell array and significantly increases the integration density of the DRAM while ensuring the electrical performance and stability of the memory cells 400.

The gate structure of the first transistor is not specifically limited in the embodiments of the present disclosure, and may be a single-gate structure, a double-gate structure, or other possible gate structures, and can be determined based on actual requirements.

For example, the first transistor may have a single-gate structure. The gate structure of the first transistor is disposed at either side of the first channel region along the third direction.

For example, the first transistor may have a double-gate structure. Referring to FIGS. 1(a) and (b) , a third gate 221 and a fourth gate 222 of the first transistor 200 are disposed at two sides of the first channel region 212 along the third direction, respectively.

Conventional transistors have only one gate to control the current in the channel region, whereas with the aforementioned technical solution, the first transistor provided in the embodiment of the present disclosure has two gates. The double-gate transistor can have twice the gate control area for the same channel region area, effectively enhancing the control capability of the gates over the channel region. This enables finer and more flexible control over carriers in the channel region by the gates, allowing more effective regulation of current turn-on and turn-off, thereby improving the switching performance of the transistor provided in the embodiment of the present disclosure. It can effectively suppress short-channel effects, which is beneficial for further reducing the size of the transistor provided in the embodiment of the present disclosure, thus increasing the storage density of the DRAM provided in the embodiment of the present disclosure. For example, under low-voltage operation, the double-gate structure of the first transistor can control the current more precisely, achieving faster switching speed, which helps to reduce the power consumption of the DRAM provided in the embodiment of the present disclosure.

It is understandable that, in conjunction with the above description of the gate structure 220, referring to FIGS. 1(a) and (1b) , along the first direction, the third gate 221, the first channel region 212, and the fourth gate 222 are stacked sequentially and are all disposed in the second notch 123. The first gate dielectric layer 240 is disposed between the third gate 221 and the first channel region 212, and between the fourth gate 222 and the first channel region 212.

The material of the gate of the first transistor is not specifically limited in the embodiments of the present disclosure. The material may be tantalum, titanium, tantalum nitride, titanium nitride, atomic crystal tungsten diselenide, atomic crystal molybdenum diselenide, or other possible materials, and can be determined based on actual requirements. Furthermore, when the first transistor has a double-gate structure, the materials of the third gate and the fourth gate may be the same to facilitate the simultaneous formation of the third gate and the fourth gate; alternatively, the materials of the third gate and the fourth gate may be different. This can be determined based on actual requirements.

Regarding the first source 231 and first drain 232, in a possible implementation, referring to FIGS. 1(a) and 1(b) , the one of the first source 231 and the first drain 232 that is electrically connected to the first gate 321 is integrally continuous with the first gate 321. One of the first source 231 and the first drain 232 that is not electrically connected to the first gate 321 is disposed in the second via 250.

With the above solution, during the manufacture of the DRAM provided in the embodiment of the present disclosure, the one of the first source and the first drain that is electrically connected to the first gate can be formed in the same process step with the first gate. This facilitates the one-time formation of a multi-layer memory cell array, significantly improving the integration density of the DRAM while ensuring the electrical performance and stability of the memory cells. Moreover, since the aforementioned two structures are integrally continuous, no additional structures are required to connect them, which helps to reduce the area occupied by the memory cell, thereby increasing the density of the DRAM provided in the embodiment of the present disclosure.

It should be noted that in FIGS. 1(a) and (1b) , the first drain 232 may be electrically connected to the first gate 321. This is only an example; the positions of the first drain 232 and the first source 231 may be swapped, and the positions of the first source region 211 and the first drain region 213 may also be swapped. The embodiments of the present disclosure do not impose specific limitations in this regard.

The materials of the first source and the first drain are not specifically limited in the embodiments of the present disclosure. The materials may be copper, aluminum, chromium, silver, gold, or other possible materials, and can be determined based on actual requirements. Furthermore, the materials of the first source and the first drain may be the same to facilitate simultaneous formation of the first source and the first drain; alternatively, the materials of the first source and the first drain may be different. This can be determined based on actual requirements.

In addition to the distribution described above, referring to FIGS. 1(a) and (1b) , the first gate dielectric layer 240 also extends to the first gate 321 and the first source 231 or first drain 232 that is integrally continuous with the first gate 321, covers the sidewall of the first notch 122, extends to the sidewall of the first via 340 such that the first gate dielectric layer 240 also serves as a part of the gate dielectric layer between the first gate 321 and the second channel region 312, and extends to cover the sidewall of the second via 250.

With the above technical solution, referring to FIGS. 1(a) and (1b) , during formation of the first gate dielectric layer 240, the material of the first gate dielectric layer 240 can be deposited directly to cover both the first notch 122 and the second via 250 after the first notch 122 and the second notch 123 communicated with the first notch 122 are formed. The first gate dielectric layers 240 for the multiple first transistors 200 in the DRAM are formed simultaneously, facilitating the one-time formation of a multi-layer memory cell array and significantly improving the integration density of the DRAM while ensuring the electrical performance and stability of the memory cells.

Regarding the material of the first gate dielectric layer, conventional materials such as silicon dioxide may be selected to reduce the process difficulty of manufacturing the first gate dielectric layer. Alternatively, high-k dielectric materials such as hafnium-based oxides, aluminum oxide, zirconium oxide, and tantalum oxide may be selected to reduce the thickness of the first gate dielectric layer, thereby reducing the volume of the first transistor. This facilitates the one-time formation of a multi-layer memory cell array and significantly improves the integration density of the DRAM while ensuring the electrical performance and stability of the memory cells.

The structure and materials of the second transistor are further explained below.

Referring to FIGS. 1(a) and (1b) , by way of example, the second transistor 300 includes: a second source region 311, a second channel region 312, a second drain region 313, a first gate 321, a second gate 322, a second source 331, a second drain 332, a dielectric isolation layer 341, and a second gate dielectric layer 342. The second source region 311, the second channel region 312, and the second drain region 313 are disposed in the first via 340 along the first direction. The second gate 322 is disposed in the first via 340, and the second channel region 312 surrounds the periphery of the second gate 322. A portion of the dielectric structure corresponding to the second channel region 312 is provided with a first notch 122 recessed inward, and the first gate 321 is disposed in the first notch 122. The second source 331 and the second drain 332 of the second transistor 300 are disposed in a third notch 333 and a fourth notch 334, respectively. The third notch 333 and the fourth notch 334 are disposed at two sides of the first gate 321 along the first direction, respectively. The second source 331 is electrically connected to the second source region 311. The second drain 332 is electrically connected to the second drain region 313. The bottom of the third notch 333 and/or the fourth notch 334 is in contact with the gate structure 220, and the inner walls of the third notch 333 and the fourth notch 334 are covered with the dielectric isolation layer 341. The dielectric isolation layer 341 electrically isolates the second source 331 and the second drain 332 from the gate structure 220. Furthermore, the dielectric isolation layer 341 and the first gate dielectric layer 240 electrically isolate the second source 331 from the first gate 321, and the second drain 332 from the first gate 321. The dielectric isolation layer 341 also covers at least the portion where the first gate 321 contacts the first via 340, so that the dielectric isolation layer 341 and the first gate dielectric layer 240 collectively serve as the gate dielectric layer between the first gate 321 and the second channel region 312.

With the aforementioned technical solution, referring to FIGS. 1(a) and(1b) , the third notch 333 and the fourth notch 334 are formed at two sides of the first notch 122 along the third direction and are connected to the first via 340. The second transistor 300 has a vertical channel structure, which reduces the area occupied by the second source region 311, the second channel region 312, and the second drain region 313 of the second transistor 300 while ensuring the channel length of the second transistor 300, thereby reducing the area occupied by the second transistor 300 and improving the storage density of the DRAM. Moreover, the second source 331, the second drain 332, and the first gate 321 of the second transistor 300 are vertically stacked along the first direction, reducing the area occupied by the second transistor 300 and improving the storage density of the DRAM. Meanwhile, the vertical stacking of the second source region 311, the second channel region 312, and the second drain region 313 in the first via 340 allows the second source region 311, the second channel region 312, and the second drain region 313 of the same second transistor 300 to be formed in the first via 340 through a single deposition step, and also allows the second source regions 311, the second channel regions 312, and the second drain regions 313 of different second transistors 300 connected via the first via 340 to be formed in the first via 340 through a single deposition step. Furthermore, only the dielectric isolation layer 341 is present between the first gate dielectric layer 240 and the second source 331 and second drain 332, preventing them from occupying additional area. This helps to reduce the area occupied by the memory cell 400, facilitating the one-time formation of a multi-layer memory cell array and significantly improving the integration density of the DRAM while ensuring the electrical performance and stability of the memory cell 400.

Referring to FIGS. 1(a) and (1b) , the first gate 321 of the second transistor 300 serves as a storage node (SN) of the 2T0C memory cell 400. Moreover, the first gate 321 is electrically connected to the first source 231 or the first drain 232. For example, the first gate 321 is integrally continuous with the first source 231 or the first drain 232.

The material of the first gate is not specifically limited in the embodiments of the present disclosure. The material may be tantalum, titanium, tantalum nitride, titanium nitride, atomic crystal tungsten diselenide, atomic crystal molybdenum diselenide, or other possible materials, and can be determined based on actual requirements.

Referring to FIGS. 1(a) and (1b) , the second source region 311, the second channel region 312, and the second drain region 313 are disposed in the first via 340 along the first direction. In other words, they cover the inner wall of the first via 340 near the first gate 321, causing the second transistor 300 to form a vertical channel.

The materials of the second source region, the second channel region, and the second drain region are not specifically limited in the embodiments of the present disclosure and can be determined based on actual requirements.

By way of example, the materials of the second source region, the second channel region, and the second drain region may be indium zinc oxide, tin-doped indium oxide, indium oxide, zinc oxide, titanium oxide, or other possible materials.

With the above technical solution, for the beneficial effects of using the aforementioned materials for the second source region, the second channel region, and the second drain region, reference can be made to the relevant description regarding the device type of the first transistor in the illustration of the first transistor, and will not be repeated here.

The positions of the second source and the second drain in the second transistor are not specifically limited in the embodiments of the present disclosure, as long as it is conducive to the parallel integration of the DRAM.

Regarding the material of the dielectric isolation layer, conventional materials such as silicon dioxide may be selected to reduce the process difficulty of manufacturing the dielectric isolation layer. Alternatively, high-k dielectric materials such as hafnium-based oxides, aluminum oxide, zirconium oxide, and tantalum oxide may be selected to reduce the thickness of the dielectric isolation layer, thereby reducing the volume of the second transistor and increasing integration density.

The materials of the second source and the second drain are not specifically limited in the embodiments of the present disclosure. The materials may be copper, aluminum, chromium, silver, gold, or other possible materials, and can be determined based on actual requirements. Furthermore, the materials of the second source and the second drain may be the same to facilitate simultaneous formation of the second source and the second drain; alternatively, the materials of the second source and the second drain may be different. This can be determined based on actual requirements.

Referring to FIGS. 1(a) and (1b) , the second gate of the second transistor is disposed in the first via 340 and on the second channel region 312.

The material of the second gate is not specifically limited in the embodiments of the present disclosure. The material may be copper, tantalum, titanium, tantalum nitride, titanium nitride, atomic crystal tungsten diselenide, atomic crystal molybdenum diselenide, or other possible materials, and can be determined based on actual requirements.

Furthermore, referring to FIGS. 1(a) and (1b) , the second channel region 312 surrounds the periphery of the second gate 322, and a second gate dielectric layer 342 is disposed between the second gate 322 and the second channel region 312.

Regarding the material of the second gate dielectric layer, conventional materials such as silicon dioxide may be selected to reduce the process difficulty of manufacturing the second gate dielectric layer. Alternatively, the material of the second gate dielectric layer may be a high-k dielectric material such as hafnium-based oxide, aluminum oxide, zirconium oxide, or tantalum oxide to reduce the thickness of the second gate dielectric layer, thereby decreasing the volume of the second transistor and improving integration density.

In practical applications, the shapes of the first via and the second via are not specifically limited in the embodiments of the present disclosure; the first via and the second via may be cylindrical holes, prismatic holes, or in other possible shapes, and the embodiments of the present disclosure impose no specific limitations. For example, the first via and the second via are both prismatic holes, and adjacent sides in the cross-sections of the first via and the second via are parallel to the second direction and the third direction, respectively.

As for the dielectric structure for isolating different memory cells, for example, the dielectric structure includes a first dielectric portion, a second dielectric portion, a first dielectric filling portion, a second dielectric filling portion, and a third dielectric filling portion.

Specifically, referring to FIGS. 1(a) and (1b) , along the first direction, the first dielectric portion 110 isolates two adjacent memory cells 400, and is recessed inward from the first via 340 to form the first notch 122, and recessed inward from the second via 250 to form the second notch 123.

Referring to FIGS. 1(a) and (1b) , along the second direction, the second dielectric portion 120 electrically isolates the first source regions 211, the first channel regions 212, the first drain regions 213, and the first gates 321 in two adjacent memory cells 400.

With the above technical solution, the second dielectric portion isolates the first source regions, the first channel regions, the first drain regions, and the first gates in two memory cells adjacent to each other in the second direction, thereby achieving isolation of data stored in the two adjacent memory cells. Additionally, the second dielectric portion can also serve as a support, preventing the stack structure from bending after formation of the first notch and the second notch, which improves the structural regularity of the memory cells. This ensures the normal operation and performance stability of the memory cells manufactured by the manufacturing method of a DRAM provided in the embodiment of the present disclosure, thereby improving yield.

The material of the second dielectric portion is not specifically limited in the embodiments of the present disclosure and can be determined based on actual requirements. For example, the material of the second dielectric portion may include silicon oxide, silicon nitride, or polysilicon.

Referring to FIGS. 1(a) and (1b) , along the second direction, the first dielectric filling portion 130 isolates two adjacent first vias 340, and the second dielectric filling portion 140 isolates two adjacent second vias 250. The third dielectric filling portion is disposed in the first via 340 and the second via 250.

The materials of the first dielectric portion, the first dielectric filling portion, the second dielectric filling portion, and the third dielectric filling portion are not specifically limited in the embodiments of the present disclosure, as long as the insulation and strength requirements are met. For example, silicon oxide or silicon nitride may be used. Furthermore, the materials of the first dielectric portion, the first dielectric filling portion, the second dielectric filling portion, and the third dielectric filling portion may be the same, making the interfaces between the portions regular and increasing the strength of the contact interfaces; alternatively, the materials of the first dielectric portion, the first dielectric filling portion, the second dielectric filling portion, and the third dielectric filling portion may be different to meet other design needs.

The distribution of the memory cells is further explained below.

Referring to the above examples and FIGS. 1(a) and (1b) , the one of the first source 231 and the first drain 232 that is not electrically connected to the first gate 321 extends along the first direction, covering the sidewall of the first dielectric portion 110 located in the second via 250, and is connected to the one of the first source 231 and the first drain 232, which is not electrically connected to the first gate 321, of the adjacent first transistor 200 along the first direction, forming a write bit line (WBL). The first gate dielectric layer 240 also extends along with the write bit line. Furthermore, the gate structure 220 is also disposed on the first dielectric portion 110 and extends along the second direction, and is connected to the gate structure 220 of the adjacent first transistor along the second direction to form a write word line (WWL). The second source 331 and the second drain 332 are also disposed on the first dielectric portion 110 and extend along the second direction, and are connected to the second source 331 and the second drain 332 of the adjacent second transistor 300 along the first direction, to form a first signal line and a second signal line, respectively. The first signal line serves as a read bit line (RBL) and the second signal line is grounded. In the first via 340, the second gate 322 extends along the first direction and is connected to the second gate 322 of the second transistor 300 adjacent along the first direction, serving as a read word line (RWL). The second source region 311, the second channel region 312, the second drain region 313, and the second gate dielectric layer 342 disposed between the second channel region 312 and the second gate 322 also extend along the first direction.

Referring to FIGS. 1(a) and (1b) , in the second via 250, multiple first transistors 200 connected to the write bit line disposed in the second via 250 form a column of first transistors 200. In the same second via 250, at least two columns of first transistors 200 are disposed and are electrically isolated by the third dielectric filling portion 150.

Referring to FIGS. 1(a) and (1b), in the first via 340, multiple second transistors 300 connected to the write bit line disposed in the first via 340 form a column of second transistors 300. In the same first via 340, at least two columns of second transistors 300 are disposed and are electrically isolated by the third dielectric filling portion 150.

According to a second aspect, an embodiment of the present disclosure further provides a manufacturing method of a DRAM. Referring to FIGS. 1(a) and (1b) , the manufacturing method of a DRAM includes: forming a plurality of memory cells 400 arranged in a three-dimensional array, and forming a dielectric structure configured to isolate the plurality of memory cells 400, where the plurality of memory cells 400 arranged in the three-dimensional array include a plurality of memory layers spaced apart along a first direction, each of the memory layers includes a plurality of memory groups spaced apart along a second direction, and each of the memory groups includes a plurality of the memory cells 400 spaced apart along a third direction. The first direction, the second direction, and the third direction are different from each other. Each of the memory cells 400 includes a first transistor 200 and a second transistor 300 distributed along the third direction. The second transistor 300 has a double-gate structure. In the same memory cell 400, one of a first source 231 and a first drain 232 of the first transistor 200 is electrically connected to a first gate 321 of the second transistor 300. A first via 340 and a second via 250 spaced apart along the third direction are provided in the dielectric structure. A second source region 311, a second channel region 312, and a second drain region 313 of the second transistor 300 are disposed in the first via along the first direction 340. A second gate 322 of the second transistor 300 is disposed in the first via 340, and the second channel region 312 of the second transistor 300 surrounds a periphery of the second gate 322. A portion of the dielectric structure corresponding to the second channel region 312 of the second transistor 300 is provided with a first notch 122 recessed inward, and the first gate 321 of the second transistor 300 is disposed in the first notch 122. One of the first source 231 and the first drain 232 that is not electrically connected to the first gate 321 is disposed in the second via 250. A portion of the dielectric structure corresponding to a portion of the second via 250 is provided with a second notch 123 recessed inward, and the second notch 123 is communicated with the first notch 122. A first source region 211, a first channel region 212, and a first drain region 213 of the first transistor 200 are distributed in the second notch along the third direction 123.

Compared with the prior art, the beneficial effects of the manufacturing method of a DRAM provided in the embodiment of the present disclosure are the same as those of the DRAM according to the first aspect, and thus will not be repeated here.

The process of manufacturing the DRAM will be described below with reference to the schematic diagrams and flowcharts of operations shown in FIGS. 1(a) and (1b) to (15a) and (15b) . For example, the manufacturing method of a DRAM includes the following steps:

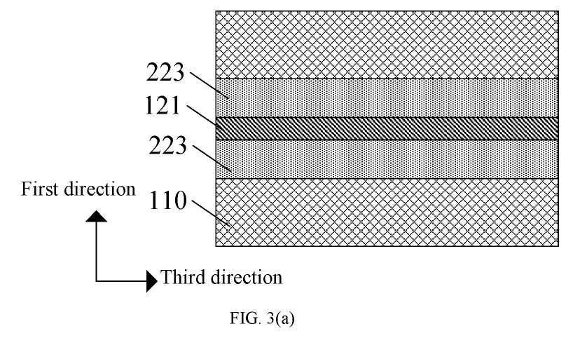

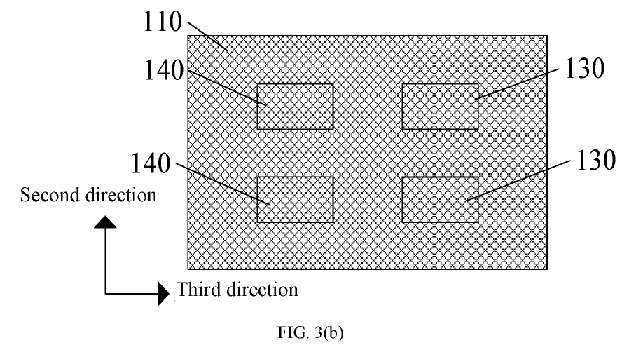

As shown in FIGS. 3(a) and (3b) , a stack structure, and a first dielectric filling portion 130 and a second dielectric filling portion 140 that penetrate through the stack structure along the first direction are formed, where the stack structure includes a plurality of stack units stacked along the first direction. The stack units each include two first dielectric layers 111 spaced apart along the first direction, and a laminate located between the two first dielectric layers 111. The laminate includes two metal layers 223 spaced apart along the first direction, and a second dielectric layer 121 located between the two metal layers 223. Materials of the first dielectric layer 111, the metal layer 223, and the second dielectric layer 121 are different from each other. Third vias 131 and fourth vias 141 penetrating along the first direction are provided in the stack structure; the third vias 131 and the fourth vias 141 are spaced apart. The third via 131 is filled with the first dielectric filling portion 130, and the fourth via 141 is filled with the second dielectric filling portion 140.

In one possible implementation, referring to FIGS. 3(a) and 3(b) , along the second direction, the first dielectric filling portion 130 is disposed between two adjacent first vias 340; along the second direction, the second dielectric filling portion 140 is disposed between two adjacent second vias 250.

Specifically, referring to FIGS. 1(a) and (1b) , the first dielectric layer 111 is used to form the first dielectric portion 110, which isolates the memory cells 400 along the first direction. The two metal layers 223 of the laminate are used to form the third gate 221 and the fourth gate 222 of the first transistor 200, and also serve as placeholder layers for forming the third notch 333 and the fourth notch 334. The second dielectric layer 121 serves as a sacrificial layer, which is subsequently partially removed to pre-reserve space for the first source region 211, the first channel region 212, the first drain region 213, the first gate 321, and the first source 231 and first drain 232 integrally continuous with the first gate 321, so as to facilitate the subsequent formation of these five structures.

Referring to FIGS. 1(a) and (1b) , it should be noted that along the first direction, the two outermost layers of the stack structure are the first dielectric layers 111, and the thickness of the two outermost first dielectric layers 111 of the stack structure may be greater than that of the first dielectric layers 111 located inside the stack structure, to protect the stack structure and other subsequently formed structures.

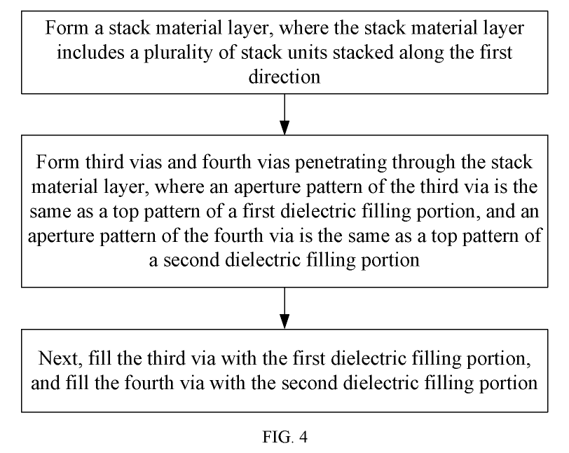

In one example, referring to FIGS. 4,(3a),(3b),5,6(a), and (6b), the forming of the stack structure, and the first dielectric filling portion 130 and the second dielectric filling portion 140 penetrating through the stack structure along the first direction, includes the following steps:

Referring to FIG. 4, a stack material layer is formed through processes such as epitaxy. The stack material layer includes the plurality of stack units stacked along the first direction.

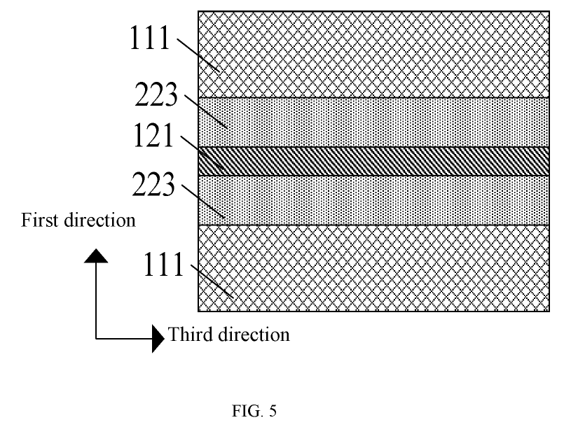

Next, referring to FIGS. 5, as well as 6(a) and 6(b), third vias 131 and fourth vias 141 penetrating through the stack material layer are formed through processes such as dry etching. Along the second direction, the third via 131 is disposed between two adjacent first vias 340. Along the second direction, the fourth via 141 is disposed between two adjacent second vias 250.

With the above technical solution, referring to FIGS. 3(a) and 3(b) , the first dielectric filling portion 130 and the second dielectric filling portion 140 serve as isolation layers between memory cells 400 adjacent to each other along the second direction, helping to prevent leakage between memory cells 400 adjacent to each other along the second direction. Moreover, in the subsequent step of partially removing the second dielectric layer 121, the two metal layers 223 in the stack unit become suspended. The first dielectric filling portion 130 and the second dielectric filling portion 140 can serve as supports, preventing the stack structure from bending, which improves the structural regularity of the memory cells 400. This ensures the normal operation and performance stability of the memory cells 400 manufactured by the manufacturing method of a DRAM provided in the embodiments of the present disclosure, thereby improving the yield.

In another example, the method for forming the stack structure, and the first dielectric filling portion and the second dielectric filling portion penetrating through the stack structure along the first direction may also involve first forming a part of the stack material layer and forming the third via and the fourth via, then forming another part of the stack material layer and forming the third via and the fourth via; and repeating the aforementioned process until the stack structure is finally formed.

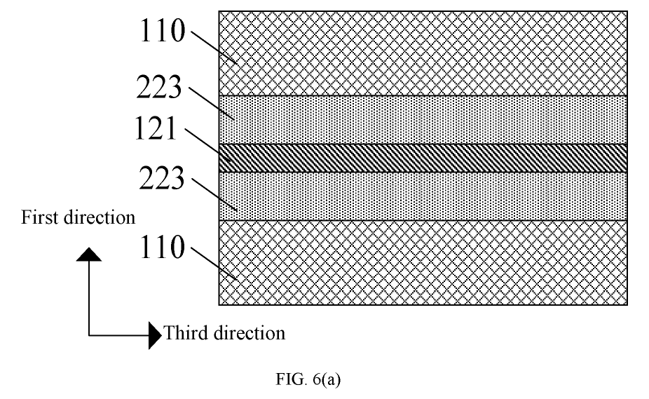

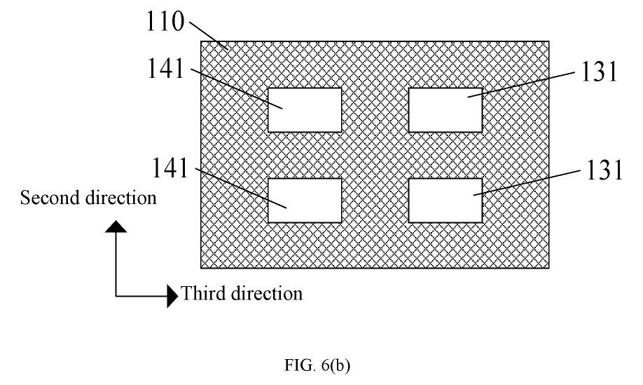

Next, referring to FIGS. 6(a) and (6b) , by using processes such as deposition, the third via 131 is filled with the first dielectric filling portion 130, and the fourth via 141 is filled with the second dielectric filling portion 140.

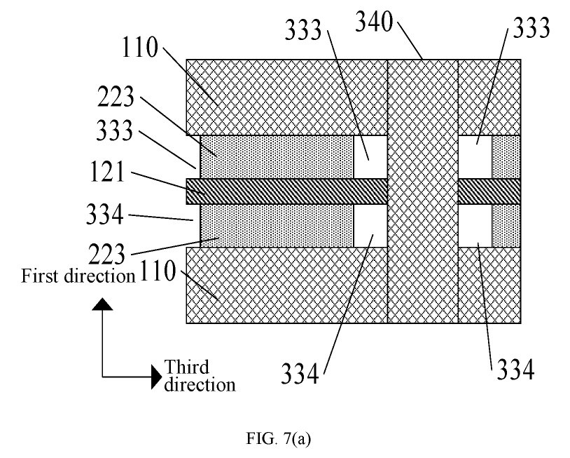

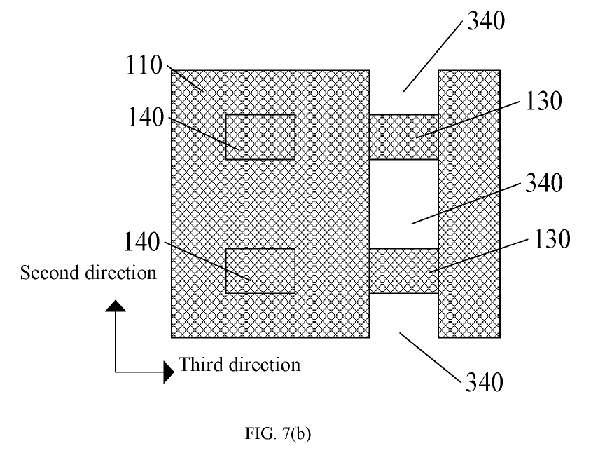

Next, referring to FIGS. 7(a) and (7b) , a plurality of first vias 340 penetrating through the stack structure and spaced apart along the second direction are formed through processes such as dry etching. Along the second direction, the first dielectric filling portion 130 is disposed between two adjacent first vias 340.

Next, referring to FIGS. 7(a) and (7b) , along the third direction, edge portions of the two metal layers 223 adjacent to the first via 340 are selectively etched through processes such as dry etching, to form the third notch 333 and the fourth notch 334.

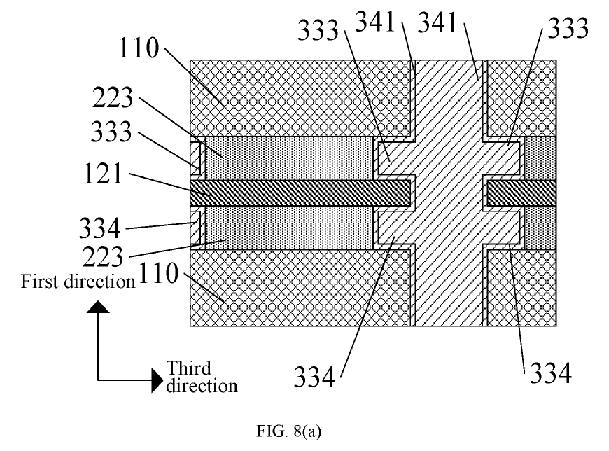

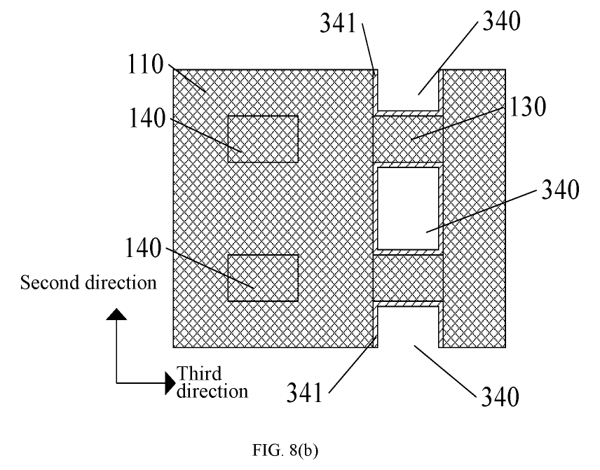

Next, referring to FIGS. 8(a) and (8b) , a dielectric isolation layer 341 is formed in the third notch 333, the fourth notch 334, and the first via 340 through processes such as deposition and selective etching processes such as dry etching.

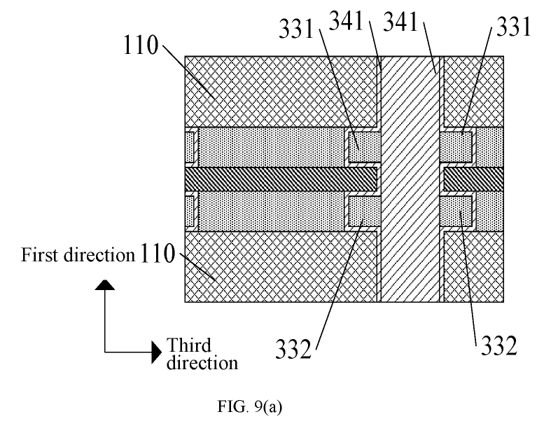

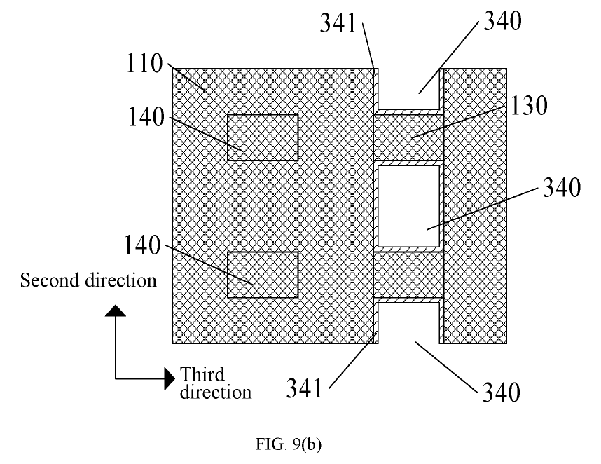

Next, referring to FIGS. 9(a) and (9b) , by using processes such as deposition and selective etching processes such as dry etching, the second source 331 of the second transistor 300 is formed in the third notch 333, and the second drain 332 of the second transistor 300 is formed in the fourth notch 334.

In the actual manufacturing process, referring to FIGS. 9(a) and (9b) , a first electrode layer may be formed in the first via 340, the third notch 333, and the fourth notch 334. Then, the portion of the first electrode layer located in the first via 340 is selectively etched to form the second source 331 and the second drain 332.

With the above technical solution, the second sources and second drains of the plurality of memory cells in the DRAM manufactured by the manufacturing method provided in the embodiments of the present disclosure can be formed simultaneously in one step. This facilitates the one-time formation of a multi-layer memory cell array, significantly improving the integration density of the DRAM while ensuring the electrical performance and stability of the memory cells.

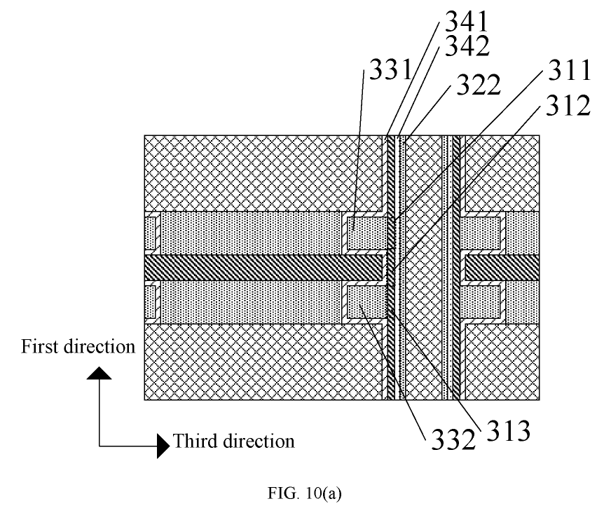

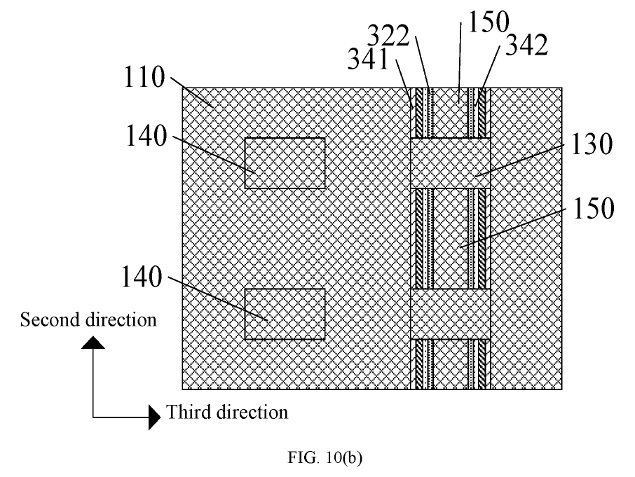

Next, referring to FIGS. 10(a) and (10b) , through processes such as deposition and selective etching processes such as dry etching, the second source region 311, the second channel region 312, and the second drain region 313 of the second transistor 300 are formed along the first direction in the first via 340. The second source 331 is connected to the second source region 311; the second drain 332 is connected to the second drain region 313.

Next, referring to FIGS. 10(a) and 10(b) , through processes such as deposition and selective etching processes such as dry etching, the second gate dielectric layer 342 of the second transistor 300 is formed in the first via 340. The second gate dielectric layer 342 is formed on the second source region 311, the second channel region 312, and the second drain region 313.

Next, referring to FIGS. 10(a) and(10b), through processes such as deposition, the second gate 322 of the second transistor 300 is formed in the first via 340.

It is understandable that, to ensure the regularity of other structures subsequently formed in the first via or to achieve electrical isolation, after forming the structures in the first via, the manufacturing method provided in the embodiment of the present disclosure further includes: selectively etching the structures formed in the first via to separate, along the third direction, the structures formed in the first via.

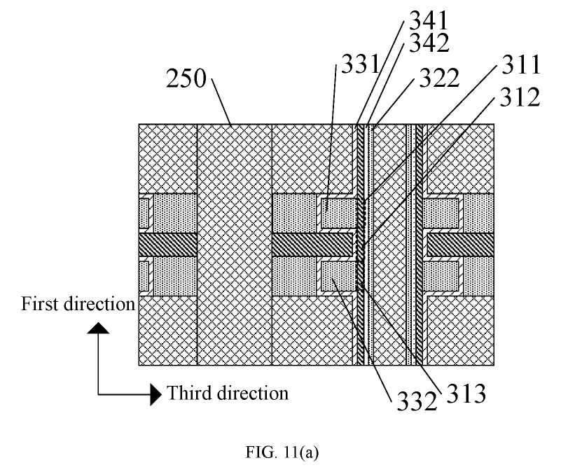

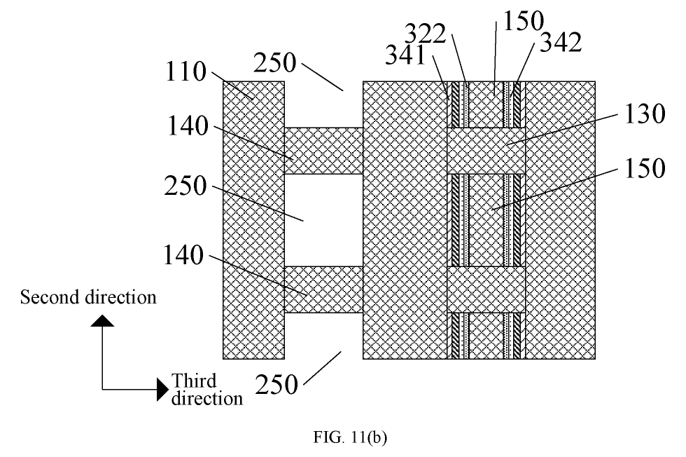

Next, referring to FIGS. 11(a) and (11b) , through processes such as dry etching, a plurality of second vias 250 penetrating through the stack structure and spaced apart along the second direction are formed. Along the second direction, the second dielectric filling portion 140 is disposed between two adjacent second vias 250.

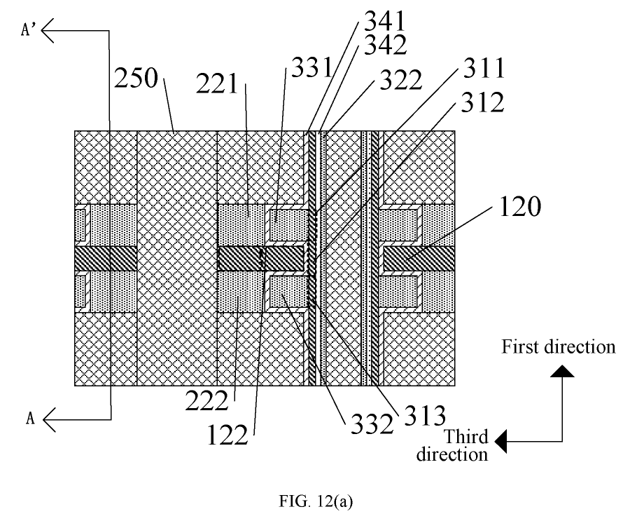

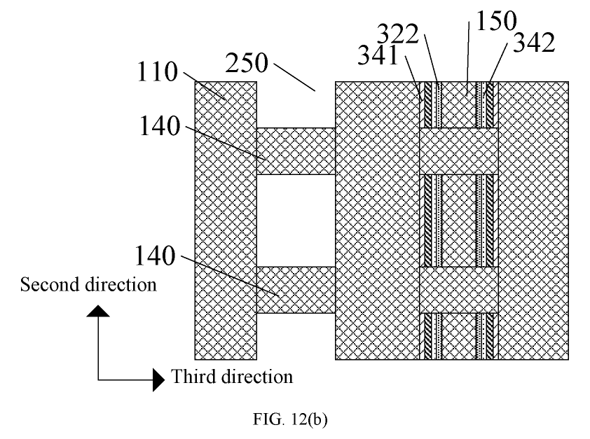

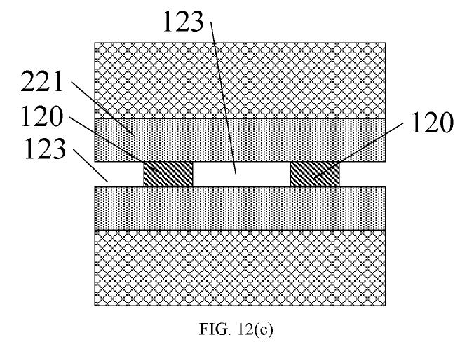

Next, referring to FIGS. 12(a) and 12(b), through dry etching or wet etching, the second dielectric layer 121 that is located between the first via 340 and the second via 250 along the third direction and adjacent to the second via 250 is partially removed, so that the remaining second dielectric layer 121 forms a second dielectric portion 120. Along the second direction, the second dielectric portion 120 electrically isolates the first source regions 211, the first channel regions 212, the first drain regions 213, and the first gates 321 in two adjacent memory cells.

With the above technical solution, the second dielectric portion isolates the first source regions, the first channel regions, the first drain regions, and the first gates in two memory cells adjacent to each other in the second direction, thereby achieving isolation of data stored in the two adjacent memory cells. Additionally, the second dielectric portion can also serve as a support, preventing the stack structure from bending after formation of the first notch and the second notch, which improves the structural regularity of the memory cells. This ensures the normal operation and performance stability of the memory cells manufactured by the manufacturing method of a DRAM provided in the embodiment of the present disclosure, thereby improving yield.

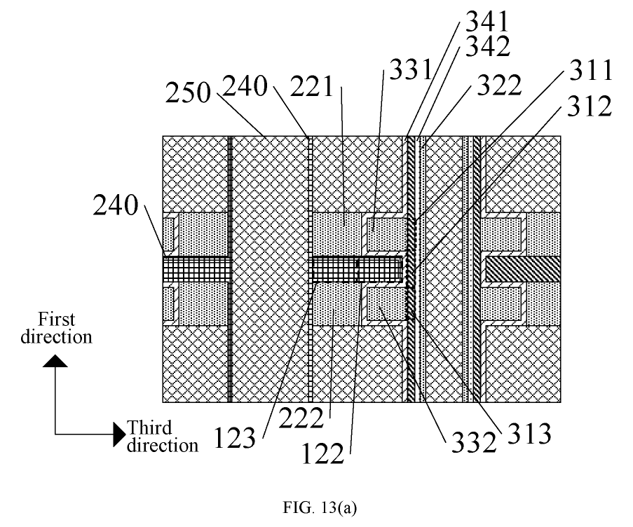

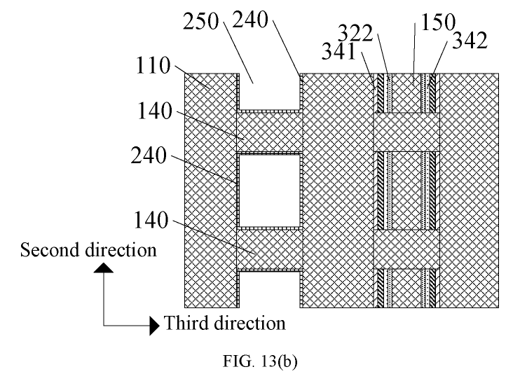

Next, referring to FIGS. 13(a) and 13(b), through processes such as deposition, the first gate dielectric layer 240 of the first transistor 200 is formed in the third notch 333 and the second via 250.

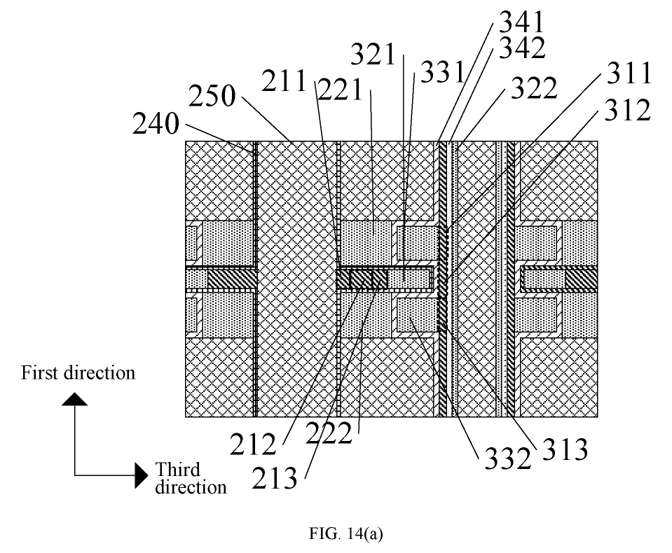

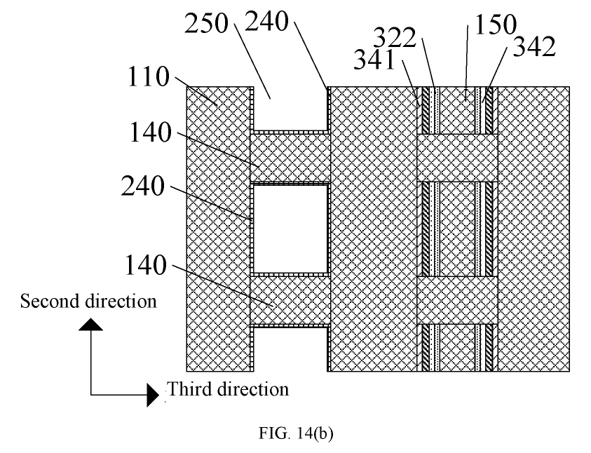

Next, referring to FIGS. 14(a) and 14(b), through processes such as deposition and selective etching processes such as dry etching, the first gate 321 of the second transistor 300 and the one of the first source 231 and the first drain 232 that is electrically connected to the first gate 321 are formed in the first notch 122, thereby forming the second transistor 300. In addition, the first source region 211, the first channel region 212, and the first drain region 213 of the first transistor 200 are formed in the second notch 123.

It is understandable that, referring to FIGS. 14(a) and 14(b), in the above process steps, the first gate 321 and the one of the first source 231 and the first drain 232 that is electrically connected to the first gate 321 are formed first, followed by the formation of the first source region 211, the first channel region 212, and the first drain region 213.

In the actual manufacturing process, referring to FIGS. 14(a) and 14(b), a second electrode layer may be formed in the second via 250, the first notch 122, and the second notch 123 through processes such as deposition. Next, portions of the second electrode layer that are located in the second via 250 and the second notch 123 are selectively etched to form the first gate 321 and the one of the first source 231 and the first drain 232 that is electrically connected to the first gate 321.

With the above technical solution, the first gates and the one of the first sources and first drains electrically connected to the first gates of the plurality of memory cells in the DRAM manufactured by the manufacturing method provided in the embodiment of the present disclosure can be formed simultaneously in one step. This facilitates the one-time formation of a multi-layer memory cell array, significantly improving the integration density of the DRAM while ensuring the electrical performance and stability of the memory cells.

Referring to the relevant description in the first aspect, the first transistor is an indium zinc oxide thin-film transistor, a tin-doped indium oxide thin-film transistor, an indium oxide thin-film transistor, a zinc oxide thin-film transistor, or a titanium oxide thin-film transistor. That is, the materials of the first source region, the first channel region, and the first drain region include: indium zinc oxide, tin-doped indium oxide, indium oxide, zinc oxide, or titanium oxide.

With the above technical solution, the aforementioned metal oxide thin-film transistors can be fabricated using low-temperature processes. Low-temperature processes can reduce the need for expensive high-temperature equipment and complex process steps, thereby lowering costs. Furthermore, in the manufacturing method provided in the embodiment of the present disclosure, the first transistor is formed after the second transistor. Fabricating the first transistor using low-temperature processes can avoid damaging other structures of the DRAM that are formed earlier, which is beneficial for the integrity of other structures of the DRAM and thus improves the yield of the DRAM.

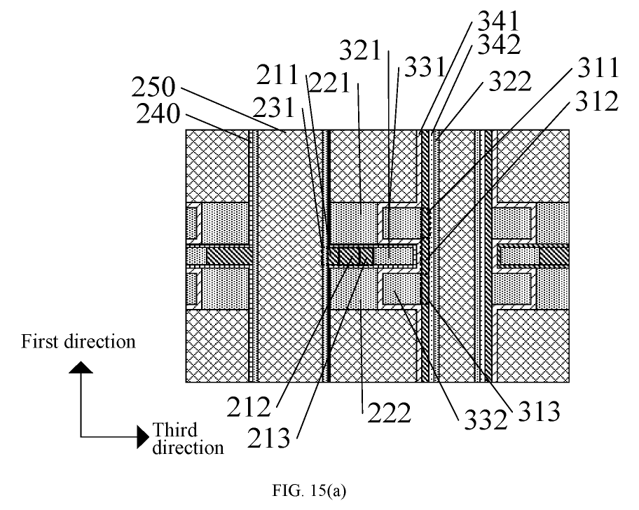

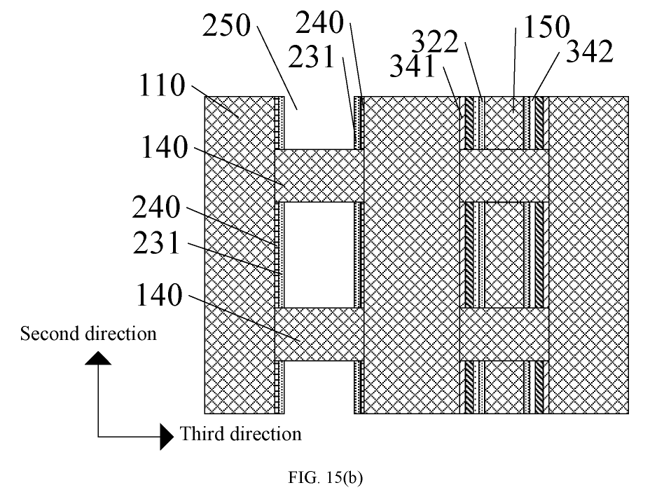

Next, through processes such as deposition and selective etching processes such as dry etching, referring to FIGS. 15(a) and 15(b), the one of the first source 231 and the first drain 232 that is not electrically connected to the first gate 321 is formed in the second via 250.

It should be noted that FIGS. 15(a) and 15(b) only show the case where the first source 231 is disposed in the second via 250. The positions of the first source 231 and the first drain 232 can be swapped, and the embodiments of the present disclosure do not impose specific limitations in this regard.

It is understandable that, to ensure the regularity of other structures subsequently formed in the second via or to achieve electrical isolation, after forming the structures in the second via, the manufacturing method provided in the embodiment of the present disclosure further includes: selectively etching the structures formed in the second via to separate, along the third direction, the structures formed in the second via.

Next, through processes such as deposition, referring to FIGS. 1(a) and 1(b) , the third dielectric filling portion 150 is formed in the second via 250.

For unelaborated details such as materials and positions of the various structures manufactured by the foregoing method of a DRAM and corresponding beneficial effects, reference can be made to the relevant descriptions in the first aspect, which will not be repeated here.

With the above technical solution, referring to FIGS. 14(a) and 14(b), the first via 340 is communicated with the first notch 122, the first via 340 is connected to the third notch 333, the first via 340 is connected to the fourth notch 334, and the second via 250 is connected to the second notch 123. After the first via 340 and the second via 250 are formed, the aforementioned structures of the first transistor 200 and the second transistor 300 are formed through processing in the first via 340 and the second via 250, thereby enabling simultaneous fabrication of memory cells 400 disposed in the same first via 340. The stack structure includes multiple first vias 340, allowing simultaneous processing of multiple memory cells 400 located in the multiple first vias 340, thereby enabling simultaneous manufacturing of all memory cells 400 in the DRAM. This facilitates the one-time formation of a multi-layer memory cell array, significantly improving the integration density of the DRAM while ensuring the electrical performance and stability of the memory cells.

In the above description, the technical details such as the composition and etching of each layer are not described in detail. However, those skilled in the art should understand that layers and regions with desired shapes can be formed by various technical means. In addition, in order to form the same structure, those skilled in the art can also design a method that is not completely the same as the method described above. In addition, although the various embodiments are described above separately, this does not mean that the measures in the various embodiments cannot be used in combination.

The embodiments of the present disclosure are described above. However, these embodiments are for illustrative purposes only, and are not intended to limit the scope of the present disclosure. The scope of the present disclosure is limited by the appended claims and legal equivalents thereof. Those skilled in the art can make various substitutions and modifications to the present disclosure without departing from the scope of the present disclosure, but such substitutions and modifications should all fall within the scope of the present disclosure.

What is claimed is:

1. A dynamic random access memory, comprising: a plurality of memory cells arranged in a three-dimensional array, and a dielectric structure configured to isolate the plurality of memory cells, wherein the plurality of memory cells arranged in the three-dimensional array comprise a plurality of memory layers spaced apart along a first direction, each of the memory layers comprises a plurality of memory groups spaced apart along a second direction, and each of the memory groups comprises a plurality of the memory cells spaced apart along a third direction; the first direction, the second direction, and the third direction are different from each other;
each of the memory cells comprises a first transistor and a second transistor distributed along the third direction; the second transistor has a double-gate structure; in the same memory cell, one of a first source and a first drain of the first transistor is electrically connected to a first gate of the second transistor;
first vias and second vias distributed at intervals along the third direction are provided in the dielectric structure; a second source region, a second channel region, and a second drain region of the second transistor are disposed in the first via along the first direction; a second gate of the second transistor is disposed in the first via, and the second channel region of the second transistor surrounds a periphery of the second gate; a portion of the dielectric structure corresponding to the second channel region of the second transistor is provided with a first notch recessed inward, and the first gate of the second transistor is disposed in the first notch; and
one of the first source and the first drain that is not electrically connected to the first gate is disposed in the second via; a portion of the dielectric structure corresponding to a portion of the second via is provided with a second notch recessed inward, and the second notch is communicated with the first notch; and a first source region, a first channel region, and a first drain region of the first transistor are distributed in the second notch along the third direction.

2. The dynamic random access memory according to claim 1, wherein the first transistor has a double-gate structure; a third gate and a fourth gate of the first transistor are disposed at two sides of the first channel region along the third direction, respectively.

3. The dynamic random access memory according to claim 1, wherein a gate structure of the first transistor is disposed in the second notch and is located on at least one side of the first channel region along the first direction; the one of the first source and the first drain that is not electrically connected to the first gate is isolated from the gate structure by a first gate dielectric layer of the first transistor.

4. The dynamic random access memory according to claim 1, wherein a second source and a second drain of the second transistor are disposed in a third notch and a fourth notch, respectively; the third notch and the fourth notch are disposed at two sides of the first gate along the first direction, respectively; the second source is electrically connected to the second source region; and the second drain is electrically connected to the second drain region.

5. The dynamic random access memory according to claim 1, wherein the first transistor is an indium zinc oxide thin-film transistor, a tin-doped indium oxide thin-film transistor, an indium oxide thin-film transistor, a zinc oxide thin-film transistor, or a titanium oxide thin-film transistor.

6. The dynamic random access memory according to claim 1, wherein the one of the first source and the first drain that is electrically connected to the first gate is integrally continuous with the first gate.
